(19) United States
(12) Patent Application Publication
(10) Pub. No.: US 2026/0293502 A1
(43) Pub. Date: Sep. 24, 2026

(54) DISPLAY APPARATUS, DISPLAY SUBSTRATE AND METHOD FOR MANUFACTURING DISPLAY SUBSTRATE

(71) Applicants: MIANYANG BOE OPTOELECTRONICS TECHNOLOGY CO., Ltd., Mianyang, Sichuan (CN); BOE Technology Group Co., Ltd., Beijing (CN)

(72) Inventors: Yong HU, Beijing (CN); Zifeng WANG, Beijing (CN); Xing LIU, Beijing (CN); Zerui ZHANG, Beijing (CN)

(21) Appl. No.: 19/479,764

(22) PCT Filed: Sep. 9, 2024
(86) PCT No.: PCT/CN2024/117743

§ 371 Date: Oct. 29, 2025

(30) Foreign Application Priority Data
Oct. 31, 2023 (CN) 202311437450.2

(51) Int. Cl. H10K 59/80; H10K 59/12; H10K 59/40

(52) U.S. Cl. CPC H10K 59/879; H10K 59/1201; H10K 59/40

(57) ABSTRACT

The present disclosure provides a display apparatus, a display substrate and a method for manufacturing a display substrate. The display substrate, in a first direction, sequentially includes: a substrate; an intermediate layer provided with a light-emitting structure; a first insulating protection layer; and a second insulating protection layer; the display substrate includes in a direction parallel to the first direction: a perforated region; a display region surrounding the perforated region; a middle region between the perforated region and the display region; and a hollowed-out region, the hollowed-out region partially overlaps with the middle region in the first direction, and the hollowed-out region is configured to disconnect the second insulating protection layer in the first direction; the first direction is a direction perpendicular to one surface of the substrate and pointing to the second insulating protection layer.

### TECHNICAL FIELD

The present disclosure relates to the field of display technology, and in particular to a display apparatus, a display substrate and a method for manufacturing a display substrate.

### BACKGROUND

A display screen is improving towards a full-screen era. In order to increase a screen-to-body ratio, most products are designed to be AA(active area)-Hole products, and the active area is perforated for a camera, to increase the screen-to-body ratio. In order to improve light extraction efficiency, two insulating protection layers (which are also called over coatings (OCs)) having different refractive indexes are designed on the uppermost layer of a conventional AMOLED (active matrix organic light-emitting diode display), which causes a portion of the OC layers in an AA Hole region to be too thick. When the display screen is heated, the OC layers shrink to generate warping, so that an edge of the AA Hole is pulled, layers are peeled, a water vapor invasion channel is formed, and GDSH (the moisture-induced oxidation of an opened region due to defects such as cracks, scratches and dents caused by encapsulation or external force) is caused. Therefore, it is desirable to provide an improved display apparatus, an improved display substrate and an improved method for manufacturing a display substrate to solve the above problems.

### SUMMARY

The present disclosure provides a display apparatus, a display substrate and a method for manufacturing a display substrate, which prevent the occurrence of GDSH.

The present disclosure provides a display substrate, sequentially including in a first direction:
a substrate;
an intermediate layer provided with a light-emitting structure;
a first insulating protection layer; and
a second insulating protection layer.

In a direction parallel to the first direction, the display substrate further includes:
a perforated region;
a display region surrounding the perforated region;
a middle region between the perforated region and the display region; and
a hollowed-out region, which partially overlaps with the middle region in the first direction, and is configured to make the second insulating protection layer broken in the first direction.

The first direction is a direction perpendicular to one surface of the substrate and pointing to the second insulating protection layer.

In some embodiments, a projection of the perforated region in the first direction falls within the hollowed-out region.

In some embodiments, a projection of a boundary of the hollowed-out region in the first direction falls within the middle region.

In some embodiments, the hollowed-out region includes a first hollowed-out region having a ring shape, and a projection of an inner boundary of the first hollowed-out region in the first direction falls within the perforated region; and a projection of an outer boundary of the first hollowed-out region in the first direction falls within the middle region.

In some embodiments, the hollowed-out region includes a second hollowed-out region having a ring shape, and a projection of each of an inner boundary and an outer boundary of the second hollowed-out region in the first direction falls within the middle region.

In some embodiments, in a portion covered by the middle region, in a direction from the perforated region to the display region, the display substrate sequentially includes a plurality of outer isolation pillars, a dam, a plurality of inner isolation pillars, and a display peripheral region.

In some embodiments, a projection of the hollowed-out region in the first direction covers the perforated region; and the projection of the hollowed-out region in the first direction covers a portion of the middle region from an edge of the perforated region to an outer isolation pillar closest to the perforated region.

In some embodiments, a projection of the hollowed-out region in the first direction covers the perforated region; and the projection of the hollowed-out region in the first direction covers a portion of the middle region from an edge of the perforated region to an inner isolation pillar farthest away from the perforated region.

In some embodiments, a projection of the hollowed-out region in the first direction covers the perforated region; and the projection of the hollowed-out region in the first direction covers a portion of the middle region from an edge of the perforated region to a portion of the display peripheral region.

In some embodiments, a portion of the second insulating protection layer disconnected by the hollowed-out region is filled with a third insulating protection layer.

In some embodiments, the hollowed-out region includes a first hollowed-out region having a ring shape, and a projection of an inner boundary of the first hollowed-out region in the first direction falls within the perforated region; and a projection of an outer boundary of the first hollowed-out region in the first direction falls between an outer isolation pillar farthest away from the perforated region and an outer isolation pillar second farthest away from the perforated region.

In some embodiments, the hollowed-out region includes:
a first hollowed-out region having a ring shape, where a projection of an inner boundary of the first hollowed-out region in the first direction falls within the perforated region; and a projection of an outer boundary of the first hollowed-out region in the first direction falls between middle two outer isolation pillars of the plurality of outer isolation pillars; and
a second hollowed-out region having a ring shape, where a projection of an inner boundary of the second hollowed-out region in the first direction falls between an inner isolation pillar closest to the dam and an inner isolation pillar second closest to the dam of the plurality of inner isolation pillars; and a projection of an outer boundary of the second hollowed-out region in the first direction falls between the display peripheral region and an inner isolation pillar closest to the display peripheral region.

In some embodiments, the hollowed-out region includes:
a first hollowed-out region having a ring shape, where a projection of an inner boundary of the first hollowed-out region in the first direction falls within the perforated region; and a projection of an outer boundary of the first hollowed-out region in the first direction falls between middle two outer isolation pillars of the plurality of outer isolation pillars; and
a second hollowed-out region having a ring shape, where a projection of an inner boundary of the second hollowed-out region in the first direction falls between an inner isolation pillar closest to the dam and an inner isolation pillar second closest to the dam of the plurality of inner isolation pillars; and a projection of an outer boundary of the second hollowed-out region in the first direction falls within the display peripheral region of the middle region.

In some embodiments, the intermediate layer in the display region includes a plurality of pixel units, the first insulating protection layer has a prism shape and surrounds pixel openings of the plurality of pixel units, the second insulating protection layer covers the first insulating protection layer, and a refractive index of the second insulating protection layer is greater than that of the first insulating protection layer.

In some embodiments, the intermediate layer in the display region further includes a sensing capacitor, and the first insulating protection layer covers the sensing capacitor.

The present disclosure further provides a method for manufacturing a display substrate, including the following steps:
forming an intermediate layer on one side of a substrate such that the intermediate layer includes a luminescent layer and a touch layer;
forming a first insulating protection layer on a side of the intermediate layer away from the substrate; and
forming a second insulating protection layer on a side of the first insulating protection layer away from the intermediate layer.

The display substrate is divided into a perforated region, a display region, a middle region and a hollowed-out region, the display region surrounds the perforated region, the middle region is disposed between the perforated region and the display region, the hollowed-out region partially overlaps with the middle region in the first direction, and a portion of the second insulating protection layer covered by the hollowed-out region in the first direction is removed.

In some embodiments, a projection of the hollowed-out region in the first direction covers the perforated region, and a projection of a boundary of the hollowed-out region in the first direction falls within the middle region, and a distance between the boundary of the hollowed-out region and a boundary of the perforated region is greater than or equal to 30 μm.

In some embodiments, the method further includes: filling the removed portion of the second insulating protection layer covered by the hollowed-out region in the first direction to form a third insulating protection layer.

In some embodiments, a dam is provided in the middle region, the hollowed-out region includes a first hollowed-out region having a ring shape, a projection of an inner boundary of the first hollowed-out region in the first direction falls within the perforated region, and a distance between the inner boundary of the first hollowed-out region and a boundary of the perforated region is greater than or equal to 30 μm; a projection of an outer boundary of the first hollowed-out region in the first direction falls within a range from the boundary of the perforated region to a side of the dam close to the perforated region, and a distance between the outer boundary of the first hollowed-out region and the boundary of the perforated region is greater than or equal to 30 μm.

In some embodiments, a plurality of inner isolation pillars are disposed on a side of the dam away from the perforated region; the hollowed-out region includes a second hollowed-out region having a ring shape, and a projection of an inner boundary of the second hollowed-out region in the first direction falls within a range from a side of the dam away from the perforated region to an inner isolation pillar closest to the display region; and a projection of an outer boundary of the second hollowed-out region in the first direction falls between the inner isolation pillar closest to the display region and a boundary of the display region.

The present disclosure further provides a display apparatus, which includes the display substrate.

Compared with the prior art, in the present disclosure, a part of the second insulating protection layer covered by the hollowed-out region is removed, so that the pulling of the edge of the AA Hole caused by warping due to shrinkage of the second insulating protection layer can be reduced, the layers can be prevented from being peeled, a water vapor invasion channel can be prevented from being formed and the occurrence of the GDSH can be avoided.

It is to be understood that, both the foregoing general description and the following detailed description are exemplary and explanatory only, and are not limiting the present disclosure.

### BRIEF DESCRIPTION OF DRAWINGS

The accompanying drawings, which are incorporated in the present disclosure and constitute a part of the present disclosure, illustrate embodiments consistent with the present disclosure, and together with the description, serve to explain the principles of the present disclosure.

FIG. 1 is a schematic top view of a display substrate according to an embodiment of the present disclosure.

FIG. 2 is a schematic diagram of a hierarchical structure of a part of a display substrate of in a display region in a display substrate according to an embodiment of the present disclosure.

FIG. 3 is a schematic diagram of a hierarchical structure of a part of a display substrate in a middle region and a perforated region according to an embodiment of the present disclosure.

FIG. 4 is a schematic top view of a touch layer of a display substrate according to an embodiment of the present disclosure.

FIG. 5 is a schematic diagram of a hierarchical structure of a part of a display substrate in a middle region and a perforated region according to an embodiment of the present disclosure.

FIG. 6 is a schematic diagram of a hierarchical structure of a part of a display substrate in a middle region and a perforated region according to an embodiment of the present disclosure.

FIG. 7 is a schematic diagram of a hierarchical structure of a part of a display panel in a middle region and a perforated region according to an embodiment of the present disclosure.

FIG. 8 is a schematic diagram of a hierarchical structure of a part of a display substrate in a middle region and a perforated region according to an embodiment of the present disclosure.

FIG. 9 is a schematic diagram of a hierarchical structure of a part of a display substrate in a middle region and a perforated region according to an embodiment of the present disclosure.

FIG. 10 is a schematic diagram of a hierarchical structure of a part of a display substrate in a middle region and a perforated region according to an embodiment of the present disclosure.

FIG. 11 is a schematic diagram of a hierarchical structure of a part of a display substrate in a middle region and a perforated region according to an embodiment of the present disclosure.

FIG. 12 is a schematic diagram of a hierarchical structure of a part of a display substrate in a middle region and a perforated region according to an embodiment of the present disclosure.

### DETAIL DESCRIPTION OF EMBODIMENTS

The exemplary embodiments will be described in detail here, and examples of the exemplary embodiments are illustrated in the accompanying drawings. The following description refers to the accompanying drawings in which the same reference numbers in different drawings represent the same or similar elements unless otherwise indicated. The implementations described in the following exemplary embodiments do not represent all implementations consistent with this description. Rather, the implementations are merely examples of apparatus and methods consistent with certain aspects of the present disclosure, as detailed in accompanying claims.

The terminology used herein is for describing the particular embodiments only and is not intended to limit the present disclosure. Unless defined otherwise, technical or scientific terms used herein shall have the ordinary meaning as understood by a person skilled in the art to which the present disclosure belongs. The terms “first”, “second”, and the like used in the description and claims are not intended to indicate any order, quantity, or importance, but rather are used for distinguishing one element from another. Further, the term “a”, “an”, “the”, or the like used herein does not denote a limitation of quantity, but rather denotes the presence of at least one element. The term “a plurality” or “some” means two or more. Unless otherwise indicated, the terms “front”, “back”, “lower”, and/or “upper”, and the like are for convenience of description, and are not limited to one position or one spatial orientation. The term “comprising”, “including”, or the like means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections.

The terminology used herein is for describing particular embodiments only and is not intended to limit the present disclosure. As used in this specification and the accompanying claims, the singular forms “a”, “an”, and “the” are intended to include the plural forms as well, unless the context clearly indicates otherwise. It should also be understood that, the term “and/or” as used herein refers to and encompasses any and all possible combinations of one or more of the associated listed items.

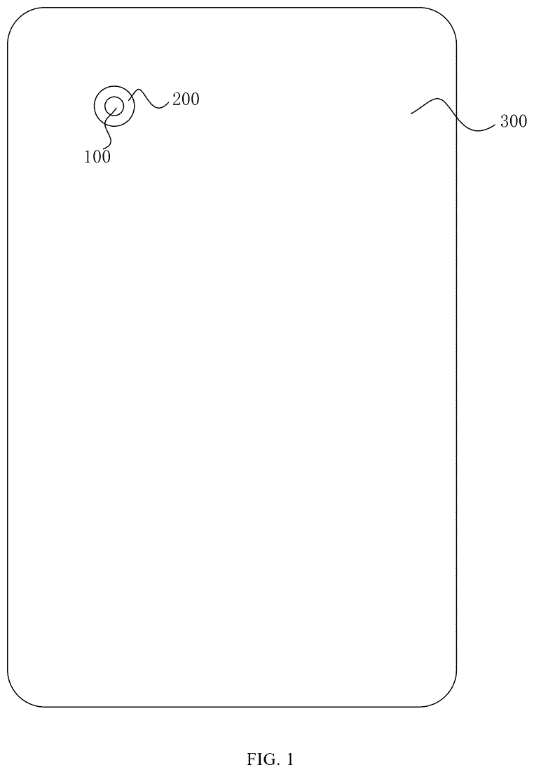

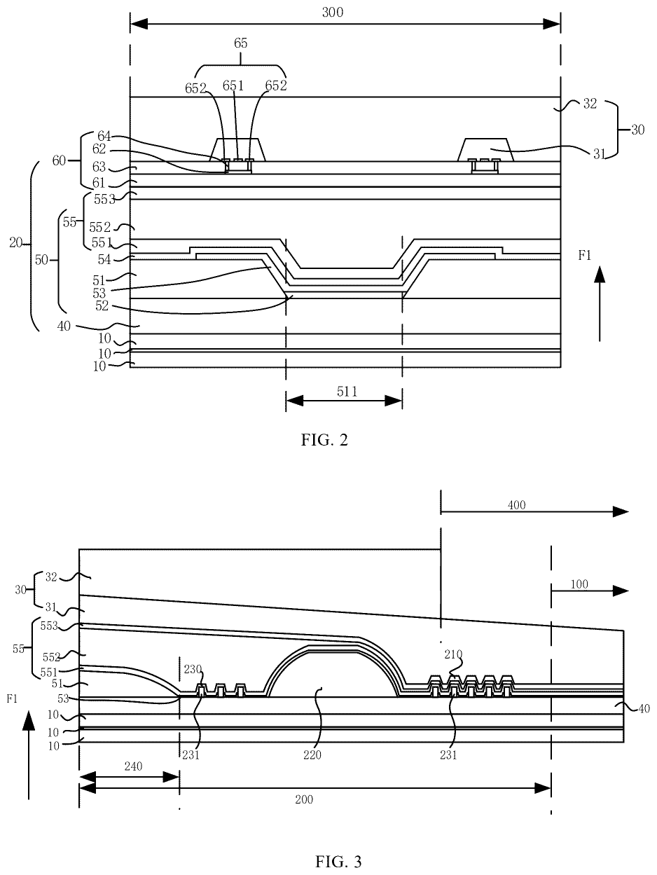

As shown in FIGS. 1 and 3, the present disclosure provides a display substrate, which sequentially includes in a first direction F1:
a substrate 10;
an intermediate layer 20 provided with a light-emitting structure;
a first insulating protection layer 31; and
a second insulating protection layer 32.

In a direction parallel to the first direction F1, the display panel further includes:
a perforated region 100;
a display region 300 surrounding the perforated region 100;
a middle region 200 disposed between the perforated region 100 and the display region 300; and
a hollowed-out region 400, which partially overlaps with the middle region 200 in the first direction F1, and is configured to make the second insulating protection layer 32 disconnected in the first direction F1.

The first direction F1 is a direction perpendicular to one surface of the substrate 10 and pointing to the second insulating protection layer 32.

In the present disclosure, the hollowed-out region 400 is provided in the display substrate, and the hollowed-out region 400 partially overlaps with the middle region 200 in the first direction F1. A part of the second insulating protection layer 32 covered by the hollowed-out region 400 is removed, so that the pulling of the edge of the perforated region 100 by the insulating protection layer when the display substrate is heated can be reduced, the layers can be prevented from being peeled, and the occurrence of the GDSH can be further avoided.

Hereinafter, various embodiments of the present disclosure conforming to the above inventive concept will be described in detail.

In the present disclosure, the first direction F1 is a direction perpendicular to a display surface and from the display substrate to a display side.

As shown in FIGS. 1 to 3, the present disclosure provides a display substrate.

The display substrate may be divided into the perforated region 100, the display region 300, and the middle region 200 between the display region 300 and the perforated region 100 in a display plane. The middle region 200 surrounds the perforated region 100 and the display region 300 surrounds the perforated region 100. The perforated region 100 covers a region corresponding to AA Hole.

The display substrate may be divided into the substrate 10, the intermediate layer 20, and an insulating protection layer 30 in the first direction F1. The substrate may be a rigid substrate. The rigid substrate may be, for example, a glass substrate or a PMMA (polymethyl methacrylate) substrate, or the like. The substrate 10 may alternatively be a flexible substrate. For example, the flexible substrate may be a PET (polyethylene terephthalate) substrate, a PI (polyimide) substrate, or a PEN (polyethylene naphthalate) substrate, or the like. The substrate may alternatively be a composite substrate composed of multiple layers of materials. It is understood that there are various types of the substrate, and the substrate may be selected according to actual needs, which is not limited in the embodiment of the present disclosure.

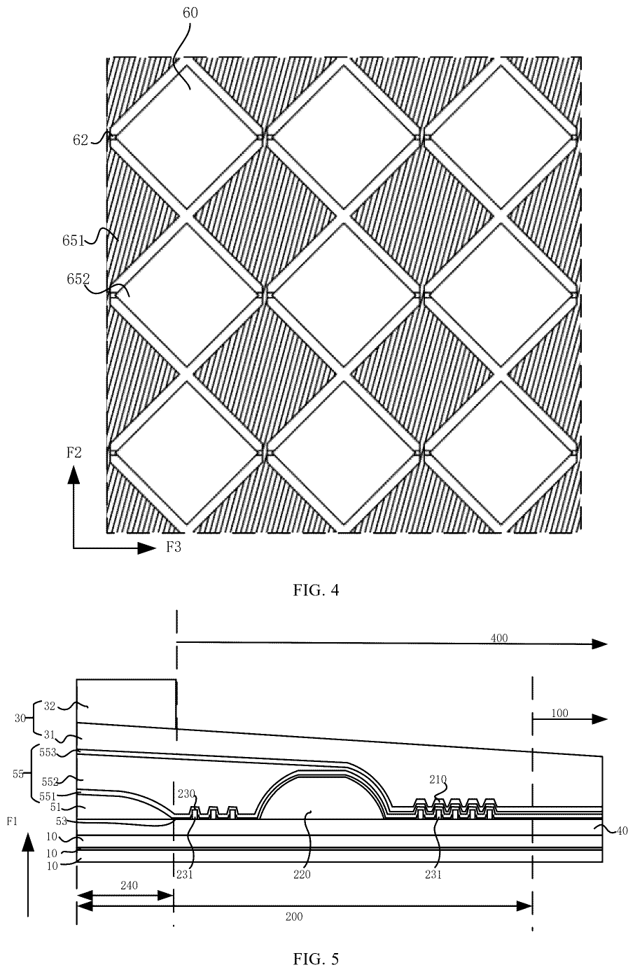

As shown in FIGS. 1 to 4, in some embodiments, in a region covered by an orthographic projection of the display region 300 in the first direction F1, the intermediate layer 20 of the display substrate includes a control layer 40, a luminescent layer 50 and a touch layer 60 in the first direction F1. The control layer 40, the luminescent layer 50 and the touch layer 60 are sequentially arranged from the substrate 10 to the insulating protection layer 30.

The control layer 40 includes a control structure (not shown) of the display substrate. The control structure controls the operation of the luminescent layer 50. In some embodiments, the control structure may be a pixel control circuit or other control structure. The pixel control circuit includes a plurality of transistors, capacitors and metal wires. The pixel control circuit may be a 2TIC control circuit, a 7T1C control circuit, or a 16T3C control circuit, or the like, as long as the pixel control circuit may control the operation of the luminescent layer 50.

The transistor includes a control electrode, a first electrode and a second electrode. The transistor used in the present disclosure may be a triode, a thin film transistor, or a field effect transistor or other device with the same characteristics. In practical operation, when the transistor is a triode, the control electrode may be a base electrode, the first electrode may be a collector electrode, and the second electrode may be an emitter electrode; alternatively, the control electrode may be a base electrode, the first electrode may be an emitter electrode, and the second electrode may be a collector electrode. In practical operation, when the transistor is a thin film transistor or a field effect transistor, the control electrode may be a gate electrode, the first electrode may be a drain electrode, and the second electrode may be a source electrode; alternatively, the control electrode may be a gate electrode, the first electrode may be a source electrode, and the second electrode may be a drain electrode.

The control layer 40 and the luminescent layer 50 are connected to each other by a conductive structure. The luminescent layer 50 includes a pixel defining layer 51, and the pixel defining layer 51 includes a plurality of opening regions 511 therein. An anode 52, a luminescent structure layer 53, and a cathode 54 are stacked in each opening region 511. The anode 52 may have a composite structure formed by sequentially stacking a transparent conductive oxide thin film/a metal thin film/a transparent conductive oxide thin film. A material of the transparent conductive oxide thin film may be, for example, any one of ITO (indium tin oxide) and IZO (indium zinc oxide), and a material of the metal thin film may be, for example, any one of gold (Au), silver (Ag), nickel (Ni), and platinum (Pt). In some examples, the anode 52 may have a composite structure of ITO/Ag/ITO. For example, the anode 52 may have a single-layer structure made of any one of ITO, IZO, Au, Ag, Ni, or Pt. A material of the cathode 54 may be any one of aluminum (Al), silver (Ag), and magnesium (Mg), or any one of a magnesium-silver alloy and an aluminum-lithium alloy. The luminescent structure layer 53 may be a luminescent structure layer 53 emitting green light, a luminescent structure layer 53 emitting blue light, or a luminescent structure layer 53 emitting red light. The three luminescent structure layers 53 emitting light of different colors are regularly distributed in a plane in the plurality of opening regions 511 in the pixel defining layer 51. The three luminescent structure layers 53 emitting light of different colors are distributed in a specific array and are controlled by the control structure of the control layer 40 to realize the display function. An encapsulation layer 55 is provided on a side of the cathode 54 away from the luminescent structure layers 53. The encapsulation layer 55 may be formed by only one layer of an inorganic material, only one layer of an organic material, or may be formed by stacking a plurality of layers of an inorganic material and an organic material. In this embodiment, the encapsulation layer 55 includes a first inorganic encapsulation layer 551 disposed on a side of the cathode 54 away from the luminescent structure layers 53, the encapsulation layer 55 further includes an organic encapsulation layer 552 disposed on a side of the first inorganic encapsulation layer 551 away from the cathode 54, and the encapsulation layer 55 further includes a second inorganic encapsulation layer 553 disposed on a side of the organic encapsulation layer 552 away from the first inorganic encapsulation layer 551. The first inorganic encapsulation layer 551 and the second inorganic encapsulation layer 553 may be made of an inorganic insulating material including nitride, oxide, oxynitride, nitrate, carbide, or any combination thereof. The organic encapsulation layer 552 may be made of an organic insulating material such as acrylic, hexamethyldisiloxane, polyacrylates, polycarbonates, or polystyrene. The organic encapsulation layer 552 may be formed of an organic material through an inkjet printing process. The first inorganic encapsulation layer 551 and the second inorganic encapsulation layer 553 may be formed through a chemical vapor deposition process.

The touch layer 60 is disposed on a side of the luminescent layer 50 away from the control layer 40. The touch layer 60 includes a buffer layer 61 disposed on a side of the luminescent layer 50 away from the control layer 40, and the buffer layer 61 may be formed of an insulating material such as silicon nitride. In this embodiment, the buffer layer 61 is disposed on a side of the second inorganic encapsulation layer 553 away from the organic encapsulation layer 552. The touch layer 60 further includes a first electrode layer 62 disposed on a side of the buffer layer 61 away from the second inorganic encapsulation layer 553. The touch layer 60 further includes a touch insulating layer 63 disposed on a side of the first electrode layer 62 away from the buffer layer 61 and covering the first electrode layer 62. The touch layer 60 further includes a second electrode layer 65 disposed on a side of the touch insulating layer 63 away from the first electrode layer 62. The second electrode layer 65 includes a plurality of first electrodes 651 arranged in a second direction F2, and the second electrode layer 65 further includes a plurality of second electrodes 652 arranged in a third direction F3. The second direction F2 intersects with the third direction F3. The plurality of first electrodes 651 arranged in the second direction F2 are directly connected to each other in the second electrode layer 65. The plurality of second electrodes 652 arranged in the third direction F3 are disconnected from each other at positions crossing the first electrodes 651 in the second electrode layer 65. The plurality of second electrodes 652 arranged in the third direction F3 are directly connected to each other through the first electrode layer 62 at the positions crossing the first electrodes 651. The touch layer 60 includes a bridge layer 64 penetrating through the touch insulating layer 63, and the bridge layer 64 is a conductive structure. The bridge layer 64 connects the second electrodes 652 and the first electrode layer 62, so that the adjacent second electrodes 652 are connected to each other through the first electrode layer 62. In this way, the plurality of first electrodes 651 arranged in the second direction F2 and the plurality of second electrodes 652 arranged in the third direction F3 form sensing capacitors at crossing points, thereby implementing a touch function. An orthographic projection of each of the crossing points of the plurality of first electrodes 651 arranged in the second direction F2 and the plurality of second electrodes 652 arranged in the third direction F3 in the first direction F1 does not overlap with the plurality of opening regions 511 of the pixel defining layer 51, that is, a projection of each sensing capacitor in the first direction F1 does not overlap with the plurality of opening regions 511.

The insulating protection layer 30 is provided on a side of the touch layer 60 away from the luminescent layer 50. The insulating protection layer 30 includes a first insulating protection layer 31 disposed on a side of the second electrode layer 65 away from the touch insulating layer 63. A projection of the first insulating protection layer 31 in the first direction F1 does not overlap with the plurality of opening regions 511 of the pixel defining layer 51. The projection of the first insulating protection layer 31 in the first direction F1 surrounds the plurality of opening regions 511 of the pixel defining layer 51. The first insulating protection layer 31 covers crossing regions of the plurality of first electrodes 651 arranged in the second direction F2 and the plurality of second electrodes 652 arranged in the third direction F3. That is, the insulating protection layer 31 covers the sensing capacitors. The first insulating protection layer 31 has a prism shape. A second insulating protection layer 32 is provided on a side of the first insulating protection layer 31 away from the touch layer 60. The second insulating protection layer 32 covers the first insulating protection layer 31 and the touch insulating layer 63. The second insulating protection layer 32 has a higher refractive index than the first insulating protection layer 31. With such a layout, the light emitted from each luminescent structure layer 53 in the corresponding opening region 511 forms a total reflection on a surface of the first insulating protection layer 31, thereby improving the light extraction efficiency of the display substrate.

As shown in FIGS. 1 to 4, in some embodiments, in a region covered by an orthographic projection of the middle region 200 in the first direction F1, in a plane perpendicular to the first direction F1 and from the perforated region 100 to the display region 300, the display substrate in the middle region 200 includes a plurality of outer isolation pillars 210, a dam 220, a plurality of inner isolation pillars 230, and a display peripheral region 240.

The display substrate in the display peripheral region 240 includes portions of elements extending from the display region 300, such as a portion of the pixel defining layer 51, a portion of the anode 52, a portion of the luminescent structure layer 53, a portion of the cathode 54, and a portion of the encapsulation layer 55 in the luminescent layer 50 (partially shown).

The number of the plurality of inner isolation pillars 230 may be set according to requirements. In some embodiments, the number of the plurality of inner isolation pillars 230 may be two, three, four, five, six, or the like. In this embodiment, the number of the plurality of inner isolation pillars 230 is three. Each inner isolation pillar 230 includes an extended portion of the luminescent structure layer 53 and an extended portion of the first inorganic encapsulation layer 551. Each inner isolation pillar 230 further includes a spacer 231 disposed under the luminescent structure layer 53, so as to elevate the portion of the luminescent structure layer 53 in the inner isolation pillar 230 in the first direction F1, thereby disconnecting the portion of the luminescent structure layer 53 in the inner isolation pillar 230 from a portion of the luminescent structure layer 53 in a region other than the inner isolation pillar 230. Thus, a contaminant such as moisture is blocked at the inner isolation pillar 230, and cannot spread into the display substrate in the luminescent structure layer 53. The first inorganic encapsulation layer 551 covers the luminescent structure layer 53, so as to form the inner isolation pillar 230. The spacer 231 may have a single metal structure or a combination of multiple metals. For example, the spacer 231 may have a titanium/aluminum/titanium stacked structure.

The number of dams 220 may be determined according to requirements. In some embodiments, the number of the dams 220 may be one, two, three, or the like. A main body of each dam 220 may be formed together with the pixel defining layer 51, a protrusion may be formed at a position of the dam 220 when the pixel defining layer 51 is formed, and a length of the protrusion in the first direction F1 is greater than a length of each of the inner isolation pillar 230 and the outer isolation pillar 210 in the first direction F1. When the organic encapsulation layer 552 is formed in the display region 300 by inkjet printing, organic substances flow. The dam 220 is disposed to block the organic substances on a side of the dam 220 away from the perforated region 100, so as to prevent the organic substances from overflowing. The protrusion is sequentially covered with the luminescent structure layer 53, the first inorganic encapsulation layer 551, the organic encapsulation layer 552, and the second inorganic encapsulation layer 553.

The number of the plurality of outer isolation pillars 210 may be set according to requirements. In some embodiments, the number of the plurality of outer isolation pillars 210 may be two, three, four, five, six, or the like. In this embodiment, the number of the plurality of outer isolation pillars 210 is three. Each outer isolation pillar 210 includes an extended portion of the luminescent structure layer 53, an extended portion of the first inorganic encapsulation layer 551, an extended portion of the organic encapsulation layer 552, and an extended portion of the second inorganic encapsulation layer 553. Each outer isolation pillar 210 further includes a spacer 231 disposed under the luminescent structure layer 53, so as to elevate the portion of the luminescent structure layer 53 in the outer isolation pillar 210 in the first direction F1, thereby disconnecting the portion of the luminescent structure layer 53 in the outer isolation pillar 210 from a portion of the luminescent structure layer 53 in a region other than the outer isolation pillar 210. Thus, a contaminant such as moisture is blocked at the outer isolation pillar 210, and cannot spread into the display substrate in the luminescent structure layer 53. The first inorganic encapsulation layer 551 covers the luminescent structure layer 53, the organic encapsulation layer 552 covers the first inorganic encapsulation layer 551, and the second inorganic encapsulation layer 553 covers the organic encapsulation layer 552, so as to form the outer isolation pillar 210. The spacer 231 may have a single metal structure or a combination of multiple metals. For example, the spacer 231 may have a titanium/aluminum/titanium stacked structure.

The display substrate in the perforated region 100 includes the substrate 10, the luminescent structure layer 53, the first inorganic encapsulation layer 551, the organic encapsulation layer 552, and the second inorganic encapsulation layer 553, in order from bottom to top. The insulating protection layer 30 covers the entire display substrate, portions of the first insulating protection layer 31 disposed in the middle region 200 and the perforated region 100 are not provided to have a prism shape, but entirely covers the middle region 200 and the perforated region 100, and the second insulating protection layer 32 also entirely covers the middle region 200 and the perforated region 100.

The display substrate further includes the hollowed-out region 400, the hollowed-out region 400 partially overlaps with the middle region 200 in the first direction F1, and the hollowed-out region 400 is configured to disconnect the second insulating protection layer 32 in the first direction F1. That is, a part of the second insulating protection layer 32 covered by the hollowed-out region 400 in the first direction F1 is removed.

In some embodiments, as shown in FIG. 3, a projection of the perforated region 100 in the first direction F1 falls within the hollowed-out region 400. That is, the hollowed-out region 400 covers the entire perforated region 100, and the hollowed-out region 400 covers a portion of the middle region 200 around the perforated region 100. In some embodiments, a projection of the boundary of the hollowed-out region 400 in the first direction F1 falls within the middle region 200. That is, the hollowed-out region 400 covers the entire perforated region 100, and the hollowed-out region 400 covers a portion of the middle region 200 around the perforated region 100.

In some embodiments, as shown in FIG. 3, a projection of the hollowed-out region 400 in the first direction F1 covers the perforated region 100. The projection of the hollowed-out region 400 in the first direction F1 covers a portion of the middle region 200 from an edge of the perforated region 100 to an outer isolation pillar 210 closest to the perforated region 100.

In some embodiments, as shown in FIG. 5, the projection of the hollowed-out region 400 in the first direction F1 covers the perforated region 100. The projection of the hollowed-out region 400 in the first direction F1 covers a portion of the middle region 200 from the edge of the perforated region 100 to the inner isolation pillar 230 farthest away from the perforated region 100.

In some embodiments, as shown in FIG. 6, the projection of the hollowed-out region 400 in the first direction F1 covers the perforated region 100. The projection of the hollowed-out region 400 in the first direction F1 covers a portion of the middle region 200 from the edge of the perforated region 100 to a part of the display peripheral region 240.

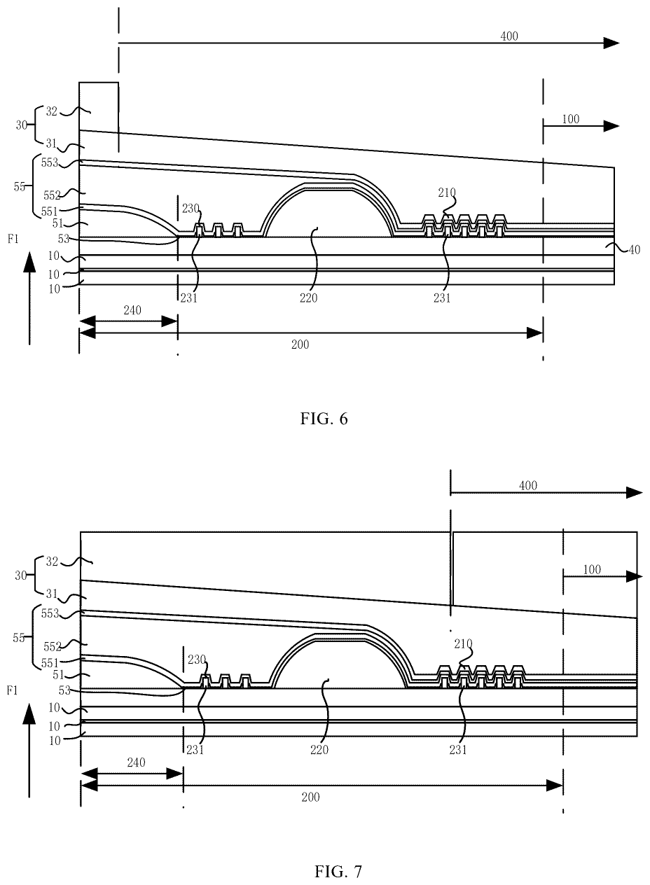

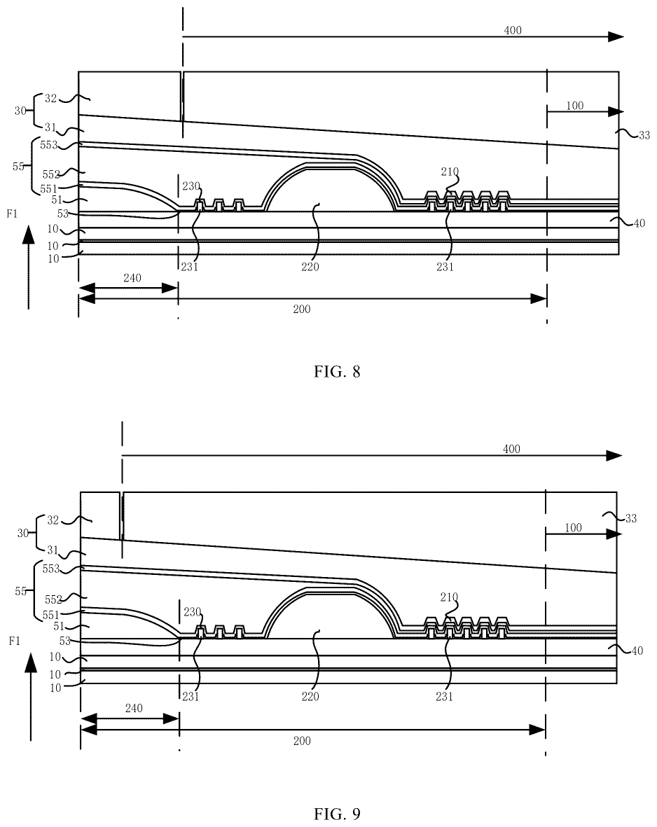

As shown in FIGS. 7 to 9, in some embodiments, a portion of the second insulating protection layer 32 disconnected by the hollowed-out region 400 is filled with a third insulating protection layer 33. The third insulating protection layer 33 may be filled by an inkjet printing process or an etching process.

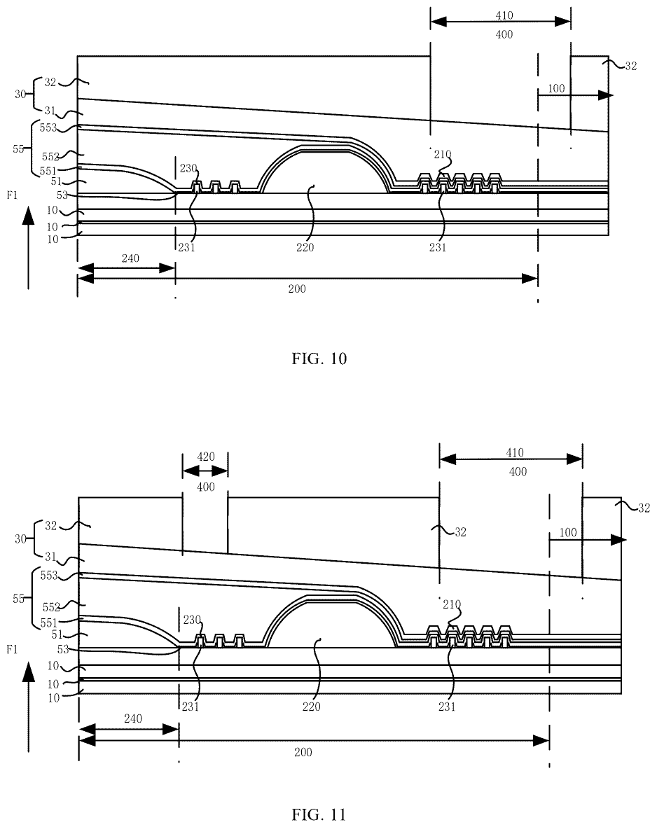

As shown in FIG. 10, in some embodiments, the hollowed-out region 400 includes a first hollowed-out region 410 having a ring shape, and a projection of an inner boundary of the first hollowed-out region 410 in the first direction F1 falls within the perforated region 100. A projection of an outer boundary of the first hollowed-out region 410 in the first direction F1 falls within the middle region 200. Therefore, a cutting line for perforating in the perforated region 100 can be avoided, and the influence of the film sticking/tearing process on the perforated region 100 during cutting can be avoided. The hollowed-out region 400 includes a second hollowed-out region 420 having a ring shape, and projections of an inner boundary and an outer boundary of the second hollowed-out region 420 in the first direction F1 fall within the middle region 200. Therefore, the second hollowed-out region 420 can release the internal stress of the layers, so that the pulling of the edge of the AA Hole when the second insulating protection layer 32 is shrunk can be reduced, the layers can be prevented from being peeled, a water vapor invasion channel can be prevented from being formed and the occurrence of the GDSH can be avoided.

As shown in FIG. 10, in some embodiments, the hollowed-out region 400 includes the first hollowed-out region 410 having a ring shape, and the projection of the inner boundary of the first hollowed-out region 410 in the first direction F1 falls within the perforated region 100. The projection of the outer boundary of the first hollowed-out region 410 in the first direction F1 falls between an outer isolation pillar 210 farthest away from the perforated region 100 and an outer isolation pillar 210 second farthest away from the perforated region 100.

As shown in FIG. 11, in some embodiments, the hollowed-out region 400 includes the first hollowed-out region 410 having a ring shape, and the projection of the inner boundary of the first hollowed-out region 410 in the first direction F1 falls within the perforated region 100. The projection of the outer boundary of the first hollowed-out region 410 in the first direction F1 falls between middle two outer isolation pillars 210 of the plurality of outer isolation pillars 210.

The hollowed-out region 400 further includes the second hollowed-out region 420 having a ring shape, and the projection of the inner boundary of the second hollowed-out region 420 in the first direction F1 falls between an inner isolation pillar 230 closest to the dam 220 and an inner isolation pillar 230 second closest to the dam 220 of the plurality of inner isolation pillars 230. The projection of the outer boundary of the second hollowed-out region 420 in the first direction F1 falls between the display peripheral region 240 and an inner isolation pillar closest to the display peripheral region 240.

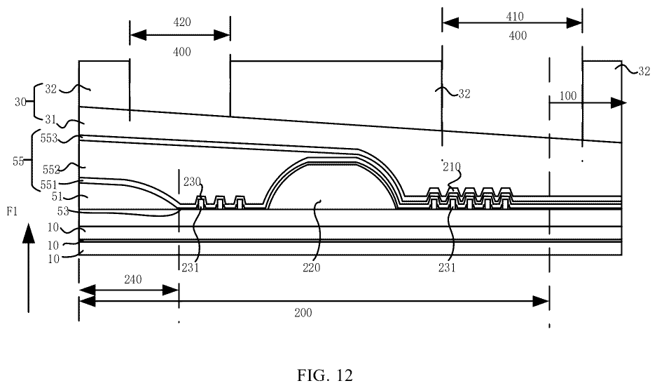

As shown in FIG. 12, in some embodiments, the hollowed-out region 400 includes the first hollowed-out region 410 having a ring shape, and the projection of the inner boundary of the first hollowed-out region 410 in the first direction F1 falls within the perforated region 100. The projection of the outer boundary of the first hollowed-out region 410 in the first direction F1 falls between middle two outer isolation pillars 210 of the plurality of outer isolation pillars 210.

The hollowed-out region 400 further includes the second hollowed-out region 420 having a ring shape, and the projection of the inner boundary of the second hollowed-out region 420 in the first direction F1 falls between an inner isolation pillar 230 closest to the dam 220 and an inner isolation pillar 230 second closest to the dam 220 of the plurality of inner isolation pillars 230. The projection of the outer boundary of the second hollowed-out region 420 in the first direction F1 falls within the display peripheral region 240 of the middle region 200.

The present disclosure further provides a method for manufacturing a display substrate, including the following steps.

An intermediate layer 20 is formed on one side of a substrate 10 such that the intermediate layer 20 includes a luminescent layer 50 and a touch layer 60.

A first insulating protection layer 31 is formed on a side of the intermediate layer 20 away from the substrate 10.

A second insulating protection layer 32 is formed on a side of the first insulating protection layer 31 away from the intermediate layer 20.

The display substrate is divided into a perforated region 100, a display region 300, a middle region 200, and a hollowed-out region 400. The display region 300 surrounds the perforated region 100. The middle region 200 is disposed between the perforated region 100 and the display region 300. The hollowed-out region 400 partially overlaps with the middle region 200 in the first direction F1, and a part of the second insulating protection layer 32 covered by the hollowed-out region 400 in the first direction F1 is removed.

As shown in FIGS. 3 to 6, in some embodiments, a projection of the hollowed-out region 400 in the first direction F1 covers the perforated region 100, and a projection of a boundary of the hollowed-out region 400 in the first direction F1 falls within the middle region 200, and a distance between the boundary of the hollowed-out-out region 400 and a boundary of the perforated region 100 is greater than or equal to 30 μm.

As shown in FIGS. 7 to 9, in some embodiments, the removed portion of the second insulating protection layer 32 covered by the hollowed-out-out region 400 in the first direction F1 is filled to form the third insulating protection layer 33.

As shown in FIGS. 10 to 12, in some embodiments, a dam 220 is provided in the middle region, the hollowed-out-out region 400 includes a first hollowed-out-out region 410 having a ring shape, and a projection of an inner boundary of the first hollowed-out region 410 in the first direction F1 falls within the perforated region 100, and a distance between the inner boundary of the first hollowed-out region 410 and the boundary of the perforated region 100 is greater than or equal to 30 μm. A projection of an outer boundary of the first hollowed-out region 410 in the first direction F1 falls within a range from the boundary of the perforated region 100 to a side of the dam 220 close to the perforated region 100, and a distance between the outer boundary of the first hollowed-out region 410 and the boundary of the perforated region 100 is greater than or equal to 30 μm.

As shown in FIGS. 10 to 12, in some embodiments, a plurality of inner isolation pillars 230 are disposed on a side of the dam 220 away from the perforated region 100. The hollowed-out region 400 includes a second hollowed-out region 420 having a ring shape, and a projection of an inner boundary of the second hollowed-out region 420 in the first direction F1 falls within a range from a side of the dam 220 away from the perforated region 100 to an inner isolation pillar 230 closest to the display region 300. A projection of an outer boundary of the second hollowed-out region 420 in the first direction F1 falls between the inner isolation pillar 230 closest to the display region 300 and a boundary of the display region 300.

The present disclosure further provides a display apparatus, which includes the display substrate.

In the present disclosure, a part of the second insulating protection layer covered by the hollowed-out region is removed, so that the pulling of the edge of the AA Hole caused by warping due to shrinkage of the second insulating protection layer can be reduced, the layers can be prevented from being peeled, a water vapor invasion channel can be prevented from being formed and the occurrence of the GDSH can be avoided.

Other embodiments of the present disclosure will be apparent to a person skilled in the art from consideration of the present disclosure and practice of the present disclosure. The present disclosure is intended to cover any variations, uses, or adaptations of the present disclosure following the general principles of the present disclosure and including the common general knowledge and the common technical means in the prior art which are not described in the present disclosure. It is intended that the present disclosure and examples be considered as exemplary only, with a true scope and spirit of the present disclosure being indicated by the accompanying claims.

It will be understood that the present disclosure is not limited to the precise arrangements that have been described above and shown in the drawings, and that various modifications and changes may be made without departing from the scope of the present disclosure. The scope of the present disclosure is limited only by the accompanying claims.

The above description is only a preferred embodiment of the present disclosure, and should not be taken as limiting the present disclosure, and any modifications, equivalent substitutions, improvements and the like made within the spirit and principle of the present disclosure should be included in the protection scope of the present disclosure.

1. A display substrate, sequentially comprising in a first direction:
a substrate;
an intermediate layer provided with a light-emitting structure;
a first insulating protection layer; and
a second insulating protection layer;
wherein in a direction parallel to the first direction, the display substrate further comprises:
a perforated region;
a display region surrounding the perforated region;
a middle region between the perforated region and the display region; and
a hollowed-out region, wherein the hollowed-out region partially overlaps with the middle region in the first direction, and the hollowed-out region is configured to disconnect the second insulating protection layer in the first direction;
wherein the first direction is a direction perpendicular to one surface of the substrate and pointing to the second insulating protection layer.

2. The display substrate of claim 1, wherein a projection of the perforated region in the first direction falls within the hollowed-out region.

3. The display substrate of claim 2, wherein a projection of a boundary of the hollowed-out region in the first direction falls within the middle region.

4. The display substrate of claim 1, wherein the hollowed-out region comprises a first hollowed-out region having a ring shape, and a projection of an inner boundary of the first hollowed-out region in the first direction falls within the perforated region; and a projection of an outer boundary of the first hollowed-out region in the first direction falls within the middle region.

5. The display substrate of claim 4, wherein the hollowed-out region comprises a second hollowed-out region having a ring shape, and a projection of each of an inner boundary and an outer boundary of the second hollowed-out region in the first direction falls within the middle region.

6. The display substrate of claim 1, wherein in a portion covered by the middle region, along a direction from the perforated region to the display region, the display substrate sequentially comprises a plurality of outer isolation pillars, a dam, a plurality of inner isolation pillars, and a display peripheral region.

7. The display substrate of claim 6, wherein a projection of the hollowed-out region in the first direction covers the perforated region; and the projection of the hollowed-out region in the first direction covers a portion of the middle region from an edge of the perforated region to an outer isolation pillar of the plurality of outer isolation pillars closest to the perforated region.

8. The display substrate of claim 6, wherein a projection of the hollowed-out region in the first direction covers the perforated region; and the projection of the hollowed-out region in the first direction covers a portion of the middle region from an edge of the perforated region to an inner isolation pillar of the plurality of inner isolation pillars farthest away from the perforated region.

9. The display substrate of claim 6, wherein a projection of the hollowed-out region in the first direction covers the perforated region; and the projection of the hollowed-out region in the first direction covers a portion of the middle region from an edge of the perforated region to a portion of the display peripheral region.

10. The display substrate of claim 1, wherein a portion of the second insulating protection layer disconnected by the hollowed-out region is filled with a third insulating protection layer.

11. The display substrate of claim 6, wherein the hollowed-out region comprises a first hollowed-out region having a ring shape, and a projection of an inner boundary of the first hollowed-out region in the first direction falls within the perforated region; and a projection of an outer boundary of the first hollowed-out region in the first direction falls between an outer isolation pillar farthest away from the perforated region and an outer isolation pillar second farthest away from the perforated region of the plurality of outer isolation pillars.

12. The display substrate of claim 6, wherein the hollowed-out region comprises:
a first hollowed-out region having a ring shape, wherein a projection of an inner boundary of the first hollowed-out region in the first direction falls within the perforated region; and a projection of an outer boundary of the first hollowed-out region in the first direction falls between middle two outer isolation pillars of the plurality of outer isolation pillars; and
a second hollowed-out region having a ring shape, wherein a projection of an inner boundary of the second hollowed-out region in the first direction falls between an inner isolation pillar closest to the dam and an inner isolation pillar second closest to the dam of the plurality of inner isolation pillars; and a projection of an outer boundary of the second hollowed-out region in the first direction falls between the display peripheral region and an inner isolation pillar closest to the display peripheral region.

13. The display substrate of claim 6, wherein the hollowed-out region comprises:
a first hollowed-out region having a ring shape, wherein a projection of an inner boundary of the first hollowed-out region in the first direction falls within the perforated region; and a projection of an outer boundary of the first hollowed-out region in the first direction falls between middle two outer isolation pillars of the plurality of outer isolation pillars; and
a second hollowed-out region having a ring shape, wherein a projection of an inner boundary of the second hollowed-out region in the first direction falls between an inner isolation pillar closest to the dam and an inner isolation pillar second closest to the dam of the plurality of inner isolation pillars; and a projection of an outer boundary of the second hollowed-out region in the first direction falls within the display peripheral region of the middle region.

14. The display substrate of claim 1, wherein the intermediate layer in the display region comprises a plurality of pixel units, the first insulating protection layer has a prism shape and surrounds pixel openings of the plurality of pixel units, the second insulating protection layer covers the first insulating protection layer, and a refractive index of the second insulating protection layer is greater than that of the first insulating protection layer.

15. The display substrate of claim 14, wherein the intermediate layer in the display region further comprises a sensing capacitor, and the first insulating protection layer covers the sensing capacitor.

16. A method for manufacturing a display substrate, comprising:
forming an intermediate layer on one side of a substrate such that the intermediate layer comprises a luminescent layer and a touch layer;
forming a first insulating protection layer on a side of the intermediate layer away from the substrate; and
forming a second insulating protection layer on a side of the first insulating protection layer away from the intermediate layer;
wherein the display substrate is divided into a perforated region, a display region, a middle region, and a hollowed-out region, the display region surrounds the perforated region, the middle region is arranged between the perforated region and the display region, the hollowed-out region partially overlaps with the middle region in a first direction, and a portion of the second insulating protection layer covered by the hollowed-out region in the first direction is removed.

17. The method of claim 16, wherein a projection of the hollowed-out region in the first direction covers the perforated region, and a projection of a boundary of the hollowed-out region in the first direction falls within the middle region, and a distance between the boundary of the hollowed-out region and a boundary of the perforated region is greater than or equal to 30 μm.

18. The method of claim 16, further comprising:
filling the removed portion of the second insulating protection layer covered by the hollowed-out region in the first direction to form a third insulating protection layer.

19. The method of claim 16, further comprising:
forming a dam in the middle region such that the hollowed-out region comprises a first hollowed-out region having a ring shape, a projection of an inner boundary of the first hollowed-out region in the first direction falls within the perforated region, and a distance between the inner boundary of the first hollowed-out region and a boundary of the perforated region is greater than or equal to 30 μm; a projection of an outer boundary of the first hollowed-out region in the first direction falls within a range from the boundary of the perforated region to a side of the dam close to the perforated region, and a distance between the outer boundary of the first hollowed-out region and the boundary of the perforated region is greater than or equal to 30 μm; and
the method further comprises: forming a plurality of inner isolation pillars on a side of the dam away from the perforated region such that the hollowed-out region comprises a second hollowed-out region having a ring shape, and a projection of an inner boundary of the second hollowed-out region in the first direction falls within a range from a side of the dam away from the perforated region to an inner isolation pillar closest to the display region; and a projection of an outer boundary of the second hollowed-out region in the first direction falls between the inner isolation pillar closest to the display region and a boundary of the display region.

20. (canceled)

21. A display apparatus, comprising the display substrate of claim 1.
